(19) United States
(12) Patent Application Publication
(10) Pub. No.: US 2008/0296572 A1
(43) Pub. Date: Dec. 4, 2008

(54) OPTICAL SEMICONDUCTOR DEVICE WITH SEALING SPACER

(75) Inventor: Patrick Daniel PERILLAT, Sassenage (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics SA, Montrouge (FR)

(21) Appl. No.: 12/167,055

(22) Filed: Jul. 2, 2008

Related U.S. Application Data
(63) Continuation-in-part of application No. 10/451,175, filed on Oct. 28, 2003.

(30) Foreign Application Priority Data
Dec. 29, 2000 (FR) 0017266

(51) Int. Cl. H01L 29/04; H01L 31/036; H01L 31/0376; H01L 31/20

(52) U.S. Cl. 257/53; 257/E31.117

(57) ABSTRACT

An optical semiconductor device may include a semiconductor component having an optical sensor on a front face thereof, and a transparent plate having electrical connection lines on a rear face thereof and lying outside a free region of the rear face. The front face of the semiconductor component may be attached to the rear face of the transparent plate so that the optical sensor is adjacent the free region. The optical semiconductor device may also include electrical connectors electrically connecting the semiconductor component to the electrical connection lines, a sealing spacer extending only partway between the front face of the semiconductor component and the rear face of the transparent plate at the periphery of the optical sensor, and an encapsulating material for encapsulating the electrical connectors and a periphery of the semiconductor component on the rear face of the transparent plate. The sealing spacer may be structurally distinct from, abutting, and retaining the encapsulating material.

### RELATED APPLICATION

The present application is a continuation-in-part of pending U.S. patent application Ser. No. 10/451,175, filed Jun. 20, 2003.

### FIELD OF THE INVENTION

The present invention relates to the field of optical semiconductor devices, and more particularly, to an optical semiconductor device fitted with a semiconductor component, one face of which has an optical sensor.

### BACKGROUND OF THE INVENTION

In the prior art, the optical semiconductor components are fitted in the bottom of the cavity of encapsulation packages which have an attached lid made of a transparent material, the bottom wall of the package being used to provide electrical connections outside the component. Such arrangements are bulky and expensive.

### SUMMARY OF THE INVENTION

An object of the present invention is to improve and simplify the optical semiconductor devices, especially reducing their bulk and their production cost.

An optical semiconductor device may include a semiconductor component having an optical sensor on a front face thereof, and a transparent plate having electrical connection lines on a rear face thereof and lying outside a free region of the rear face. The front face of the semiconductor component may be attached to the rear face of the transparent plate so that the optical sensor is adjacent the free region. The optical semiconductor device may also include electrical connectors electrically connecting the semiconductor component to the electrical connection lines, a sealing spacer extending only partway between the front face of the semiconductor component and the rear face of the transparent plate at the periphery of the optical sensor, and an encapsulating material for encapsulating the electrical connectors and a periphery of the semiconductor component on the rear face of the transparent plate. The sealing spacer may be structurally distinct from, abutting, and retaining the encapsulating material.

The optical semiconductor device may further comprise an adhesive layer securing the sealing spacer to the front face of the semiconductor component. Moreover, the encapsulating material may extend into a gap between the sealing spacer and the rear face of the transparent plate.

In other embodiments, the optical semiconductor device further comprises an adhesive layer securing the sealing spacer to the rear face of the transparent plate. Moreover, the encapsulating material may extend into a gap between the sealing spacer and the front face of the semiconductor component.

More particularly, the sealing spacer may have a thickness between 70% and 95% of a distance between the front face of the semiconductor component and the rear face of the transparent plate. The electrical connectors may comprise electrical connection balls between the front face of the semiconductor component and the rear face of the transparent plate and being placed at the periphery of the optical sensor. Also, the transparent plate may comprise a glass plate.

In certain embodiments, the optical semiconductor device may further comprise a printed circuit board. The transparent plate may be mounted on the printed circuit board via electrical connectors connected to the electrical connection lines. The printed circuit board may comprise an opening in which the semiconductor component lies.

### BRIEF DESCRIPTION OF THE DRAWINGS

The present invention may be better understood on studying an optical semiconductor device described by way of non-limiting example and illustrated by drawings in which:

FIG. 1 is a cross-sectional view of an optical semiconductor device according to the present invention.

FIG. 2 is a front view of the optical semiconductor device of FIG. 1.

FIG. 3 is a cross-sectional view of an assembly including the optical semiconductor device of FIG. 1.

FIG. 4 is a cross-sectional view of another embodiment of the optical semiconductor device according to the present invention.

FIG. 5 is a cross-sectional view of yet another embodiment of the optical semiconductor device according to the present invention.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and multiple prime notation is used to indicate similar elements in alternative embodiments.

The optical semiconductor device 1 shown in the figures comprises an optical semiconductor component 2 which has, on the central part of its front face 4, an optical sensor 3 and, at the periphery and at some distance from this optical sensor 3, electrical connection pads 5. The optical semiconductor device 1 in addition comprises a plate 6 made of a transparent material such as glass, with a larger area than that of the optical sensor 3, on the rear face 7 of which are made electrical connection tracks or lines 8 which are in the form of segments made of an electrically conducting material. These segments 8 lie in the pattern of a star on the peripheral part of the rear face 7 leaving a central open region.

The optical component 2 is mounted on and electrically connected to the glass plate 6 via a multiplicity of conducting balls 9, for example made of metal, which are soldered, on the one hand, to the pads 5 of the front face 4 of the optical component 2 and, on the other hand, to the inner ends of the electrical connection segments 8, such that the rear face 4 of the optical component 2 lies at some distance from the rear face 7 of the glass plate 6.

In the space separating the periphery of the optical sensor 3 and the electrical connection balls 5, a seal 10 forming an annular spacer is inserted and is, for example, adhesively bonded between the front surface 4 of the optical component 2 and the rear face 7 of the glass plate 6. The peripheral interface region between the optical semiconductor component 2 and the rear face 7 of the glass plate 6 is filled with an encapsulation material 11 which forms a sealing ring which, in addition, encapsulates the electrical connection balls 9 and extends inward, being retained therein by the seal 10, the electrical connection segments 8 lying below and outside this sealing ring 11.

Thus, the optical sensor of the optical component 2 lies at some distance from the rear face 7 of the glass plate 6 and the interface region separating them is protected by virtue of the seal 10 and the sealing ring 11. Electrical connection balls 12, which extend to the periphery and lie at some distance from the optical component 2 and from the sealing ring 11, are soldered to the outer end parts of the electrical connection lines 9.

With reference to FIG. 3, it can be seen that the optical semiconductor component 1 is attached and electrically connected to a printed circuit 13 via electrical connection balls 12. The rear face 7 of the glass plate 6 consequently lies at some distance from a face 14 of the printed circuit 13, the latter having a recess or a through-passage 13a in which the semiconductor component 2 is freely engaged. The printed circuit 13 is fitted in a container 15 which has a channel 16 lying in front of the front face of the glass plate 6 and in which are arranged, on the side of the glass plate 6, a lens 17 and, on the outside, a glass plate 18.

The optical sensor 3 of the semiconductor component 2 may thus form an optical sensor for light rays passing through the channel 16 of the container 15 by passing through the glass plate 18 and the lens 17 and also passing through the glass plate 6 carrying the optical semiconductor component 1.

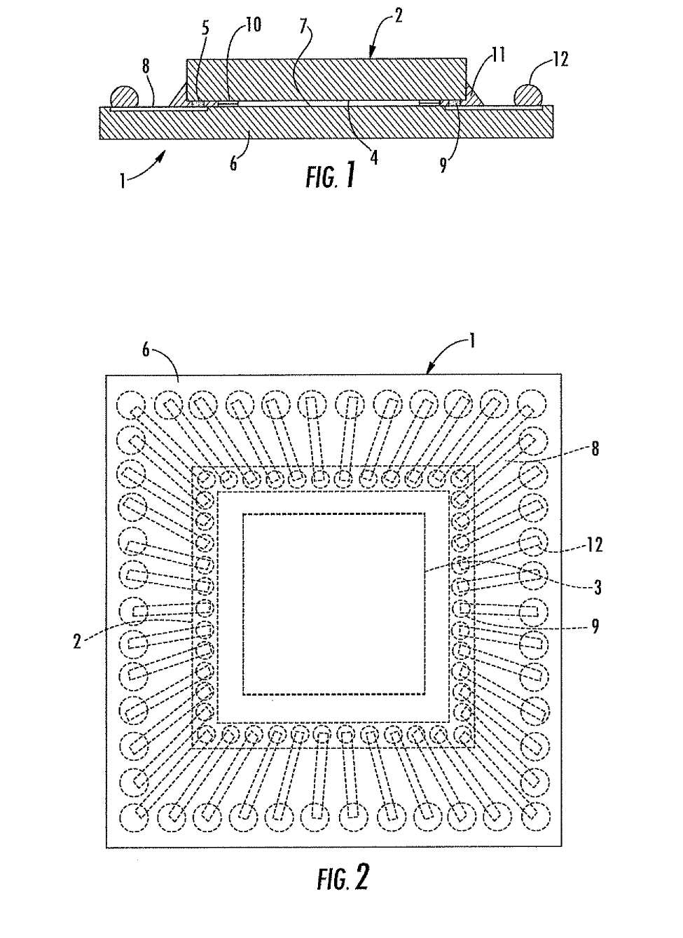

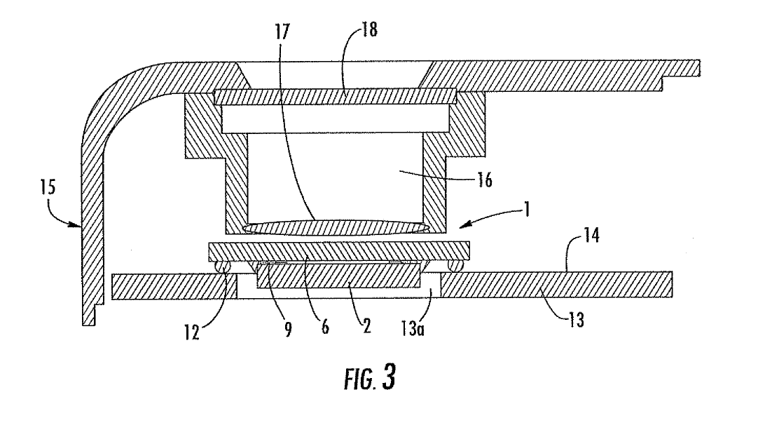

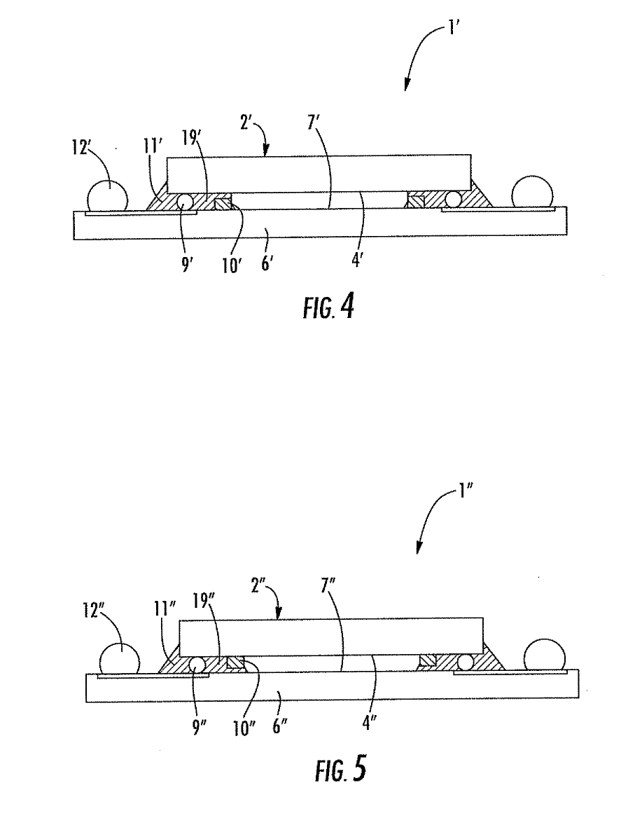

Referring now to FIG. 4, another embodiment of the optical semiconductor device 1′ is now described. In this embodiment of the optical semiconductor device 1′, those elements already discussed above with respect to FIGS. 1-3 are given prime notation and most require no further discussion herein. This embodiment differs from the previous embodiment in that the seal 10 is replaced by a seal 10′ which is adhesively bonded on the rear face 7′ of the plate 6′ and has a thickness which is less than the distance between the front face 4, of the semiconductor component 2′ and the rear face 7′ of the plate 6′, so as to form an initial gap 19′ between the seal 10′ and the front face 4′ of the semiconductor component 2′.

Thereafter, the sealing ring 11′ may have a part which extends in the gap 19′ as shown in the illustrated embodiment. The thickness of the seal 10′ can be between seventy and ninety five percent of this distance between the faces. So, for example, after having fixed this seal 10′ and the balls 9′ on the rear face of the plate 6′, the semiconductor component 2′ can be placed with a tool (not shown). The existence of the gap 19′ permits regulation or control of the position of the semiconductor component 2′ with respect to the plate 6′ and ensures that the balls are well connected. After that, the sealing ring 11′ can be formed and the material thereof is retained by the seal 10′ but can enter in the gap 19′, without contaminating the opposed active faces of the semiconductor component 21 and the plate 6′.

Referring now to FIG. 5, another embodiment of the optical semiconductor device 1″ is now described. In this embodiment of the optical semiconductor device 1″, those elements already discussed above with respect to FIGS. 1-3 are given double prime notation and most require no further discussion herein. This embodiment differs from the previous embodiment in that the seal 10 is replaced by a seal 10″ adhesively bonded on the front face 4″ of the semiconductor component 2″ and has a thickness less than the distance between the front face 4″ of the semiconductor component 2″ and the rear face 7″ of the plate 6″, so as to form an initial gap 19″ between the seal 10″ and the rear face 7″ of the plate 6″.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. An optical semiconductor device comprising:
a semiconductor component including an optical sensor on a front face thereof;
a transparent plate including electrical connection lines on a rear face thereof and lying outside a free region of the rear face;
the front face of said semiconductor component being attached to the rear face of said transparent plate so that said optical sensor is adjacent the free region;
electrical connectors electrically connecting said semiconductor component to said electrical connection lines;
a sealing spacer extending only partway between the front face of said semiconductor component and the rear face of said transparent plate at the periphery of said optical sensor; and
an encapsulating material for encapsulating said electrical connectors and a periphery of said semiconductor component on the rear face of said transparent plate;
said sealing spacer being structurally distinct from, abutting, and retaining said encapsulating material.

2. The optical semiconductor device according to claim 1 further comprising an adhesive layer securing said sealing spacer to the front face of said semiconductor component.

3. The optical semiconductor device according to claim 2 wherein said encapsulating material extends into a gap between said sealing spacer and the rear face of said transparent plate.

4. The optical semiconductor device according to claim 1 further comprising an adhesive layer securing said sealing spacer to the rear face of said transparent plate.

5. The optical semiconductor device according to claim 4 wherein said encapsulating material extends into a gap between said sealing spacer and the front face of said semiconductor component.

6. The optical semiconductor device according to claim 1 wherein said sealing spacer has a thickness between 70% and 95% of a distance between the front face of said semiconductor component and the rear face of said transparent plate.

7. The optical semiconductor device according to claim 1 wherein said electrical connectors comprise electrical connection balls between the front face of said semiconductor component and the rear face of said transparent plate and placed at the periphery of said optical sensor.

8. The optical semiconductor device according to claim 1 wherein said transparent plate comprises a glass plate.

9. The optical semiconductor device according to claim 1 further comprising a printed circuit board; wherein said transparent plate is mounted on said printed circuit board via electrical connectors connected to said electrical connection lines; and wherein said printed circuit board comprises an opening in which said semiconductor component lies.

10. An optical semiconductor device comprising:
a semiconductor component including an optical sensor on a front face thereof;
a transparent plate including electrical connection lines on a rear face thereof and lying outside a free region of the rear face;
the front face of said semiconductor component being attached to the rear face of said transparent plate so that said optical sensor is adjacent the free region;
electrical connection balls electrically connecting said semiconductor component to said electrical connection lines and being between the front face of said semiconductor component and the rear face of said transparent plate at the periphery of said optical sensor;
a sealing spacer extending only partway between the front face of said semiconductor component and the rear face of said transparent plate at the periphery of said optical sensor; and
an encapsulating material for encapsulating said electrical connectors and a periphery of said semiconductor component on the rear face of said transparent plate;
said sealing spacer being structurally distinct from, abutting, and retaining said encapsulating material and having a thickness between 70% and 95% of a distance between the front face of said semiconductor component and the rear face of said transparent plate.

11. The optical semiconductor device according to claim 10 further comprising an adhesive layer securing said sealing spacer to the front face of said semiconductor component.

12. The optical semiconductor device according to claim 11 wherein said encapsulating material extends into a gap between said sealing spacer and the rear face of said transparent plate.

13. The optical semiconductor device according to claim 10 further comprising an adhesive layer securing said sealing spacer to the rear face of said transparent plate.

14. The optical semiconductor device according to claim 13 wherein said encapsulating material extends into a gap between said sealing spacer and the front face of said semiconductor component.

15. A method of making an optical semiconductor device comprising:
providing a semiconductor component including an optical sensor on a front face thereof, and a transparent plate including electrical connection lines on a rear face thereof and lying outside a free region of the rear face;
mounting the front face of the semiconductor component to the rear face of the transparent plate so that the optical sensor is adjacent the free region;
electrically connecting the semiconductor component to the electrical connection lines with electrical connectors;
providing a sealing spacer extending only partway between the front face of the semiconductor component and the rear face of the transparent plate at the periphery of the optical sensor; and
encapsulating the electrical connectors and a periphery of the semiconductor component with an encapsulating material on the rear face of the transparent plate, the sealing spacer being structurally distinct from, abutting, and retaining the encapsulating material.

16. The method according to claim 15 further comprising securing the sealing spacer to the front face of the semiconductor component with an adhesive layer.

17. The method according to claim 16 wherein the encapsulating material extends into a gap between the sealing spacer and the rear face of the transparent plate.

18. The method according to claim 15 further comprising securing the sealing spacer to the rear face of the transparent plate with an adhesive layer.

19. The method according to claim 18 wherein the encapsulating material extends into a gap between the sealing spacer and the front face of the semiconductor component.

20. The method according to claim 15 wherein the sealing spacer has a thickness between 70% and 95% of a distance between the front face of the semiconductor component and the rear face of the transparent plate.

21. The method according to claim 15 wherein the electrical connectors comprise electrical connection balls between the front face of the semiconductor component and the rear face of the transparent plate and placed at the periphery of the optical sensor.
